(19) United States
(12) Patent Application Publication
(10) Pub. No.: US 2020/0251379 A1
(43) Pub. Date: Aug. 6, 2020

(54) SEMICONDUCTOR DEVICE AND FABRICATION METHOD THEREOF

(71) Applicants: Semiconductor Manufacturing International (Shanghai) Corporation, Shanghai (CN); Semiconductor Manufacturing International (Beijing) Corporation, Beijing (CN)

(72) Inventor: Nan WANG, Shanghai (CN)

(21) Appl. No.: 16/749,119

(22) Filed: Jan. 22, 2020

(30) Foreign Application Priority Data
Jan. 31, 2019 (CN) 201910097600.7

(51) Int. Cl. H01L 21/762; H01L 27/088; H01L 21/8234

(52) U.S. Cl. CPC H01L 21/76224; H01L 21/31111; H01L 21/823481; H01L 27/0886

(57) ABSTRACT

Fabrication method and semiconductor device are provided. The method includes: providing a substrate including a first region, a second region and a third region arranged sequentially along a first direction; forming fins on the substrate with an extending direction parallel to the first direction; forming gate structures on the first region and the third region across the fins, and forming a sacrificial gate structure across the fins; forming a dielectric layer over the substrate; forming a mask layer on the dielectric layer including a first opening and a second opening; and removing the sacrificial gate structure under a bottom of the first opening, a portion of fins under a bottom of the first opening, and a portion of gate structures exposed by the second opening, by using the mask layer as an etch mask, to form a first groove and a second groove.

### CROSS-REFERENCES TO RELATED APPLICATION

This application claims the priority of Chinese Patent Application No. 201910097600.7, filed on Jan. 31, 2019, the content of which is incorporated herein by reference in its entirety.

### TECHNICAL FIELD

The present disclosure generally relates to the field of semiconductor technology and, more particularly, relates to a semiconductor device and its fabrication method.

### BACKGROUND

As semiconductor technologies develop rapidly, semiconductor devices are developed toward a direction with a higher device density and a higher integration level. A transistor is one of the most fundamental devices and is widely used. With developments of the semiconductor technologies, the controlling ability of a conventional planar transistor on channel currents becomes weaker, causing short channel effects and serious leakage current problems. The semiconductor device has a poor performance.

Transistors with three-dimensional structures such as fin field-effect transistors (FinFETs) become hot topics of the current semiconductor field. A FinFET is a multi-gate device. The FinFET usually includes a plurality of thin fins on a surface of a substrate extending upwards along a direction perpendicular to the surface of the substrate. Channels for the FinFET are formed in the plurality of fins, and gates fare formed on the plurality of fins. Sources and drains are formed in fins at sides of each gate. Adjacent fins are separated by isolation structures.

As devices are miniaturized gradually, new technologies including a single-diffusion-break process are developed to form the isolation structures, for fins with a smaller size and a large destruction density. In the single-diffusion-beak process, the isolation structures are distributed along a length direction of the fins. Some regions of the fins are removed to form one or more break grooves in the fins. The one or more break grooves are filled with insulating materials including SiO₂, and the fins are partitioned into a plurality of small fins. Leakage currents between adjacent regions of the fins and between two adjacent fins are prevented. Also, bridging connections between source regions and drain regions formed in the fins are avoided.

However, a process for forming a semiconductor device with the single-diffusion-break isolation structures is complex. Therefore, there is a need to provide a fabrication method for a semiconductor device with a simplified process. The disclosed methods and semiconductor devices are directed to solve one or more problems set forth above and other problems in the art.

### SUMMARY

One aspect of the present disclosure provides a fabrication method for a semiconductor device. The method includes: providing a substrate including a first region, a second region and a third region arranged sequentially along a first direction; forming a plurality of fins on the substrate; forming a plurality of gate structures on the first region and the third region of the substrate; forming a sacrificial gate structure on the second region of the substrate; forming a dielectric layer on the substrate covering the plurality of fins, the plurality of gate structures, and the sacrificial gate structure; forming a mask layer on the dielectric layer including a first opening and a second opening; and removing the sacrificial gate structure under a bottom of the first opening, a portion of the plurality of fins under a bottom of the first opening, and the portion of the plurality of gate structures exposed by the second opening, by using the mask layer as an etch mask, to form a first groove and a second groove in the dielectric layer. Each of the plurality of fins extends parallel to the first direction from the first region to the third region through the second region. The plurality of gate structures crosses the plurality of fins and extends along a second direction perpendicular to the first direction. The sacrificial gate structure crosses the plurality of fins and is parallel to the plurality of gate structures. The dielectric layer exposes a top surface of the sacrificial gate structure and top surfaces of the plurality of gate structures. The first opening is located in the second region of the substrate and exposes the sacrificial gate structure. The second opening is located on the first region and the third region of the substrate and exposes a portion of the plurality of gate structures on the first region and the third region of the substrate. The first groove is located on the second region of the substrate and exposes the sacrificial gate structure. The second groove is located in the first region and the third region of the substrate.

Another aspect of the present disclosure provides a semiconductor device. The device includes: a substrate including a first region, a second region and a third region; a plurality of fins on the substrate; a plurality of gate structures on the first region and the third region of the substrate; a dielectric layer on the substrate; a first groove; and a second groove. The first region, the second region, and the third region are arranged sequentially along a first direction. Each of the plurality of fins is discrete from each other and extends parallel to the first direction. The plurality of gate structures crosses the plurality of fins and extends along a second direction perpendicular to the first direction. The dielectric layer covers the plurality of fins, the plurality of gate structures, and the sacrificial gate structure. The dielectric layer exposes a top surface of the sacrificial gate structure and top surfaces of the plurality of gate structures. The first groove and the second groove are located in the dielectric layer. The first groove is located on the second region of the substrate, and the second groove is located on the first region and the third region of the substrate.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIGS. 1-5 illustrate semiconductor structures corresponding to certain stages for forming a semiconductor device;

FIGS. 6-18 illustrate semiconductor structures corresponding to certain stages for forming an exemplary semiconductor device according to various disclosed embodiments of the present disclosure; and

FIG. 19 illustrates an exemplary method for forming a semiconductor device according to various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width and depth should be considered during practical fabrication.

FIGS. 1-5 illustrate semiconductor structures corresponding to certain stages for forming a semiconductor device.

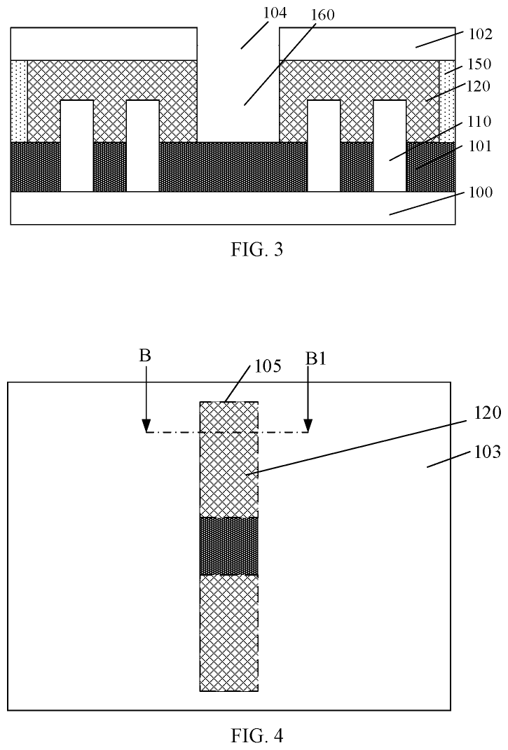

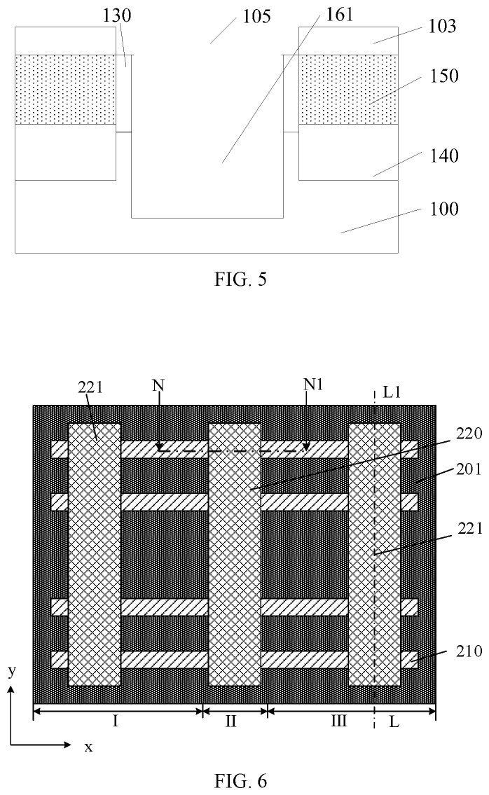

As illustrated in FIG. 1 showing a top view of a semiconductor device, a semiconductor substrate 100 (shown in FIG. 3) may be provided. A plurality of fins 110 may be formed on the semiconductor substrate 100. The plurality of fins 110 may extend along a first direction. An isolation structure 101 may be formed on the semiconductor substrate 100. A sacrificial gate structure 120 and gate structures 121 may be formed on the isolation structure 101 and may cross the plurality of fins 110. The gate structures 121 may extend along a second direction. After forming the sacrificial gate structure 120 and the gate structures 121, source/drain doped layers 140 (shown in FIG. 5) may be formed in fins at sides of each of the gate structures 121 and at sides of the sacrificial gate structure 120.

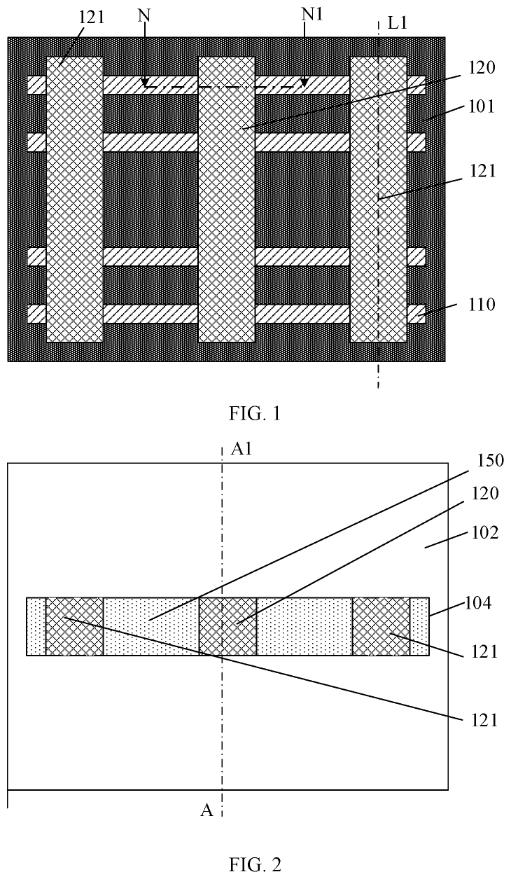

As illustrated in FIG. 2, after forming the source/drain doped layers 140, a dielectric layer 150 may be formed on the isolation structure 101. The dielectric layer 150 may cover sidewalls of the sacrificial gate structure 120 and sidewalls of the gate structures 121, and may expose a top surface of the sacrificial gate structure 120 and top surfaces of the gate structures 121. A first mask layer 102 may be formed on the dielectric layer 150. The first mask layer 102 may include a first opening 104 exposing a portion of the top surface of the sacrificial gate structure 120 and a portion of the top surfaces of the gate structures 121.

As shown in FIG. 3 illustrating a cross-section of the semiconductor device based on a cross-section in FIG. 2 along an A-A1 direction, a portion of the sacrificial gate structure 120 and a portion of the gate structures 121 exposed by the first opening 104 may be etched away by using the first mask layer 102 as a mask, to form a first groove 160.

After forming the first groove 160, the first mask layer 102 may be removed.

As illustrated in FIG. 4, after the first mask layer 102 is removed, a second mask layer 103 may be formed on the dielectric layer 150. The second mask layer 103 may include a second opening 105 exposing the top surface of the sacrificial gate structure 120. The second opening 105 may extend along the second direction.

As illustrated in FIG. 5 showing a cross-section of the semiconductor device in FIG. 4 along a B-B1 direction, the sacrificial gate structure 120 exposed by the second opening 105 and a portion of the plurality of fins covered by the sacrificial layer 120 may be etched away by using the second mask layer as a mask, to form a second groove 161. The second groove 161 may extend along the second direction.

Subsequently, a single-diffusion-break isolation structure may be formed in the first groove, to achieve isolation of fields in different regions. An isolation layer may be formed in the second groove to separate gate structures in different regions. The sacrificial gate structure and the gate structures may be formed simultaneously, and the sacrificial gate structure may occupy a position of the single-diffusion-break isolation structure. Correspondingly, the position of the single-diffusion-break isolation structure may be controlled precisely. However, the first groove 160 and the second groove 161 may be formed at different times, and materials of the gate structures may be etched twice. The etching process of the gate structures may be complicated. Also, the first groove 160 and the second groove 161 formed by etching at different times may have poor accuracy, and the formed semiconductor device may have poor performance.

The present disclosure provides a semiconductor device and fabrication method thereof to at least partially resolved above problems. In the fabrication method, a mask layer including a first opening and a second opening may be formed on a dielectric layer. A first groove and a second groove may be formed by etching with the mask layer as a mask. The first groove and the second groove may be formed simultaneously. A fabrication process may be simplified and producing efficiency may be improved.

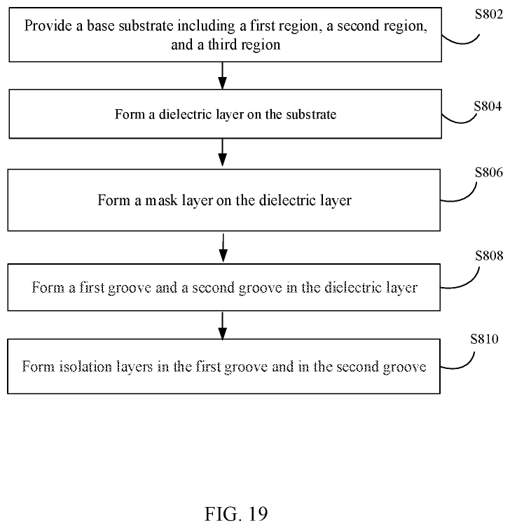

FIGS. 6-18 illustrate semiconductor structures corresponding to certain stages for forming an exemplary semiconductor structures according to various disclosed embodiments of the present disclosure; and FIG. 19 illustrates an exemplary method for forming a semiconductor device according to various disclosed embodiments of the present disclosure.

As illustrated in FIG. 6 showing a top view of the semiconductor structure, a substrate 200 may be provided (e.g., S802 in FIG. 19).

The substrate 200 may include a first region I, a second region II, and a third region III arranged along a first direction x.

The substrate 200 may be made of a semiconductor material including silicon, germanium, SiGe, GaAs, AsGaIn. Silicon may be single-crystalline silicon, polycrystalline silicon, or amorphous silicon. The substrate 200 may also be a semiconductor-on-insulator structure. The semiconductor-on-insulator structure may include an insulator and a semiconductor material layer on the insulator. The semiconductor material layer may be made of a semiconductor material including silicon, germanium, SiGe, GaAs, and AsGaln.

In one embodiment, the substrate 200 may be made of single-crystalline silicon.

A plurality of fins 210 may be formed on the substrate 200. The plurality of fins 210 may be parallel to each other, and parallel to the first direction x. Each of the plurality of fins 210 may extend from the first region I to the third region III through the second region II.

In one embodiment, the plurality of fins 210 may be formed by patterning the substrate 200. In other embodiments, the plurality of fins 210 may be formed by: forming a fin material layer on the substrate 200 and patterning the fin material layer to form the plurality of fins 210.

In one embodiment, the plurality of fins may be made of a material including single-crystalline silicon. In other embodiments, the plurality of fins may be made of a material including single-crystalline silicon and other semiconductor materials.

In one embodiment, an isolation structure 201 may be formed on the substrate 200. The isolation structure 201 may cover a portion of sidewalls of the plurality of fins 210. The isolation structure 201 may be made of a material including SiO₂.

A plurality of gate structures 221 may be formed in the first region I of the substrate 200 and in the third region III of the substrate 200. Each of the plurality of gate structures 221 may cross the plurality of fins 210, and may extend along a second direction y perpendicular to the first direction x.

In various embodiments, each of the plurality of gate structures 221 may include a gate dielectric layer and a gate layer on the gate dielectric layer. The gate dielectric layer may be made of a high-K dielectric material. The gate layer may be made of a metal including Cu, W, Ni, Cr, Ti, Ta, Al, or a combination thereof.

In one embodiment, each of the plurality of gate structures 221 may include a gate oxidation layer and a gate layer on the gate oxidation layer. The gate oxidation layer may be made SiO₂, and the gate layer may be made of polycrystalline silicon.

A sacrificial gate structure 220 may be formed on the second region II of the substrate 200. The sacrificial gate structure 220 may cross the plurality of fins 210 and may be parallel to the plurality of gate structures 221.

In one embodiment, the sacrificial gate structure 220 may include a sacrificial gate oxidation layer and a sacrificial gate layer on the gate oxidation layer. The sacrificial gate oxidation layer may be made SiO₂, and the sacrificial gate layer may be made of polycrystalline silicon.

In one embodiment, the sacrificial gate structure 220 may be formed when forming the plurality of gate structures 221.

The sacrificial gate structure 220 and the plurality of gate structures 221 may be formed simultaneously, and the sacrificial gate structure may occupy a position of a single-diffusion-break isolation structure. Correspondingly, the position of the single-diffusion-break isolation structure may be controlled precisely.

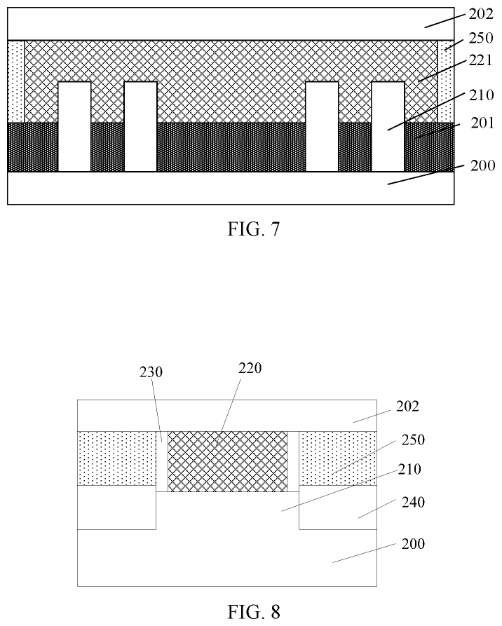

FIG. 7 shows a cross-sectional structure based on a structure along L-L1 direction in FIG. 6, and FIG. 8 shows a cross-sectional structure based on a structure along N-N1 direction in FIG. 6. As shown in FIG. 7 and FIG. 8, a dielectric layer 250 may be formed on the substrate 200 (e.g., S804 in FIG. 19). The dielectric layer 250 may cover the plurality of fins 210, the sacrificial layer 220, and the plurality of gate structures 221. The dielectric layer 250 may expose a top surface of the sacrificial gate structure 220 and top surfaces of the plurality of gate structures 221.

In one embodiment, after forming the sacrificial gate structure 220 and the plurality of gate structures 221, and before forming the dielectric layer 250, source/drain doped layers 240 may be formed in fins 210 at sides of each of the plurality of gate structures 221 and at sides of the sacrificial gate structure 220.

The source/drain doped layers 240 may be formed by an ion implantation process. Ions may be implanted into the fins 210 at sides of each of the plurality of gate structures 221 and at sides of the sacrificial gate structure 220, to form the source/drain doped layers 240.

In one embodiment, after forming the sacrificial gate structure 220 and the plurality of gate structures 221, and before forming the dielectric layer 250, spacers 230 may be formed on sides of each of the plurality of gate structures 221 and on sides of the sacrificial gate structure 220. The spacers 230 may protect the plurality of gate structures 220 and may be made of a material including SiNx.

An initial mask material layer 202 may be formed on the dielectric layer 250, to cover the sacrificial gate structure 220 and the plurality of gate structures 221.

The initial mask material layer 202 may provide a material layer for forming a mask layer subsequently.

The initial mask material layer 202 may be formed by a chemical vapor deposition process, a physical vapor deposition process, or an atomic layer deposition process.

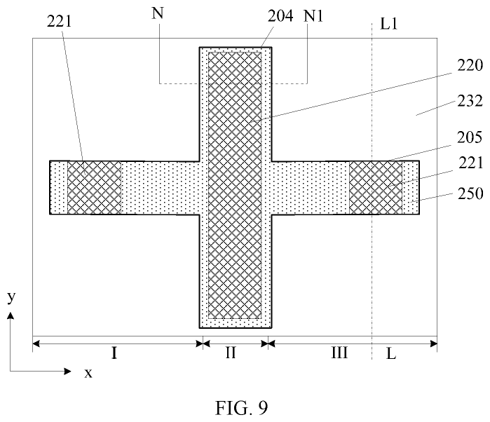

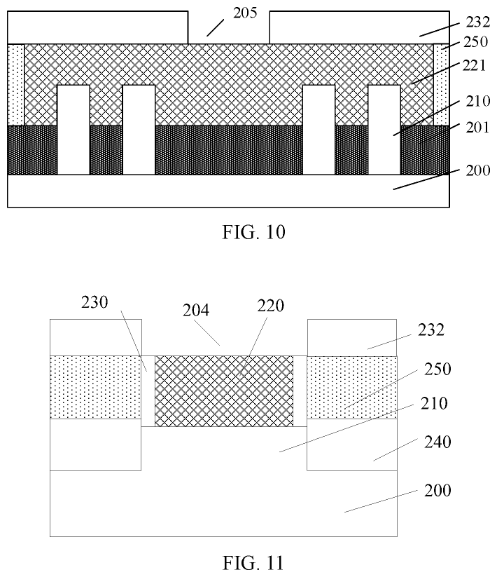

As illustrated in FIG. 9 showing a top view of the semiconductor device, FIG. 10 showing a cross-section along an L-L1 direction in FIG. 9, and FIG. 11 showing a cross-section along an N-N1 direction in FIG. 9, a mask layer 232 may be formed on the dielectric layer 250 (e.g., S806 in FIG. 19). The mask layer 232 may include a first opening 204 and a second opening 205. The first opening 204 may be disposed on the second region II of the substrate 200. The second opening 205 may be disposed on the first region I and the third region III of the substrate 200. The first opening 204 may expose the sacrificial gate structure 220, and the second opening 205 may expose a portion of the plurality of gate structures 221 on the first region I and the third region III of the substrate 200.

The second opening 205 may also expose a portion of the dielectric layer 250 on the first region I and the third region III of the substrate 200.

The mask layer 232 may be formed by: forming a first patterned layer on the initial mask material layer 202 to expose a portion of the initial mask material layer 202 on the sacrificial gate structure 220; etching the initial mask material layer 202 by using the first patterned layer as a mask, to form an initial mask layer with the first opening 204 exposing the sacrificial gate structure 220; forming a second patterned layer on the initial mask layer to expose a portion of the initial mask layer on the portion of the plurality of gate structures 221 on the first region I and the third region III of the substrate 200; etching the initial mask layer by using the second patterned layer as a mask, to form the mask layer 232 with the second opening 205.

The first patterned layer and the second patterned layer may be made of photoresist.

The first patterned layer may be removed after forming the first opening 204. The second patterned layer may be removed after forming the second opening 205, to expose the surface of the mask layer 232. The first patterned layer and the second patterned layer may be removed by a process including an ashing method.

The mask layer 232 may be formed by etching the initial mask layer. The initial mask layer may include the first opening 204, and the mask layer 232 may include the first opening 204 and the second opening 205 correspondingly.

The mask layer 232 may be made of a material including SiNₓ, SiNB, SiCNO, SiNO, or a combination thereof.

In one embodiment, the mask layer 232 may be made of SiNₓ.

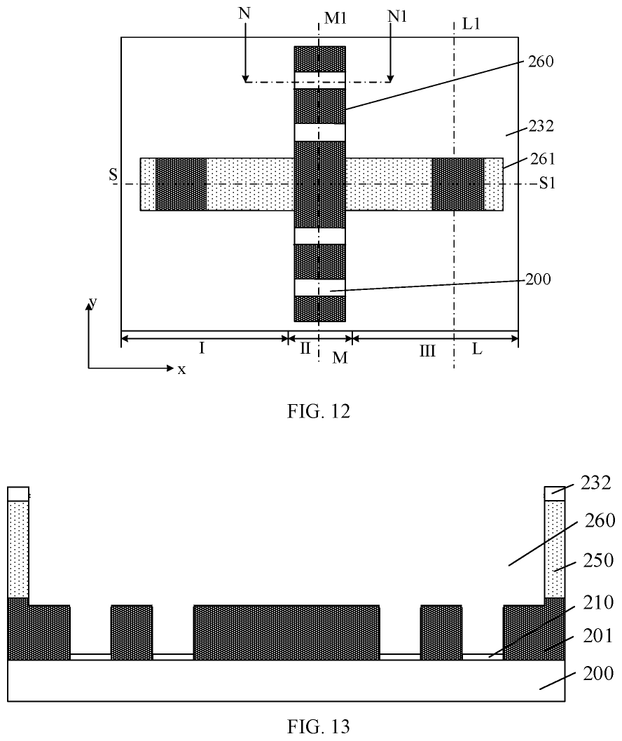

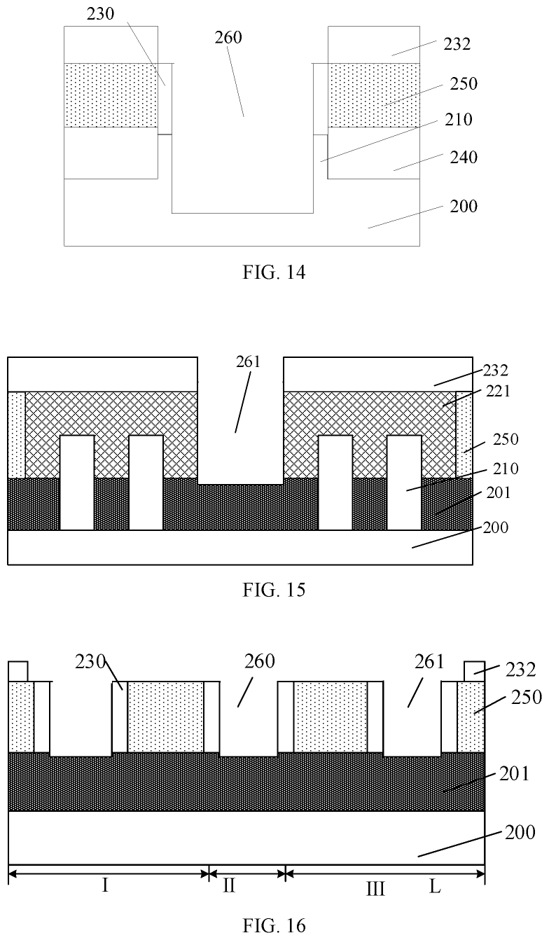

FIG. 12 is based on FIG. 9, FIG. 13 is a cross-section view along an M-M1 direction in FIG. 12, FIG. 14 is a cross-section view along an N-N1 direction in FIG. 12, FIG. 15 is a cross-section view along an L-L1 direction in FIG. 12, and FIG. 16 is a cross-section view along an S-S1 direction in FIG. 12. As illustrated in FIGS. 12-16, the sacrificial gate structure 221 and a portion of the plurality of fins 210 under a bottom of the first opening 204, and a portion of the plurality of gate structures 221 exposed by the second opening 205, may be etched by using the mask layer 232 as a mask, to form a first groove 260 and a second groove 261 in the dielectric layer 250 (e.g., S808 in FIG. 19). The first groove 260 may be located on the second region II of the substrate 200, while the second groove 261 may be located on the first region I and the third region III of the substrate 200.

The sacrificial gate structure 221 and the portion of the plurality of fins 210 under the bottom of the first opening 204, and the portion of the plurality of gate structures 221 exposed by the second opening 205, may be etched by a dry etching method, a wet etching method, or a combination thereof.

The sacrificial gate layer and the sacrificial gate oxidation layer of the sacrificial gate structure 221 exposed by the bottom of the first opening 204 and the portion of the plurality of fins 210 under the bottom of the first opening 204 may be etched to form the first groove 260.

The portion of the plurality of gate structures 221 exposed by a bottom of the second opening 205, may be etched to form the second groove 261.

In one embodiment, a process for etching the sacrificial gate structure 221 and the portion of the plurality of fins 210 under the bottom of the first opening 204, and the portion of the plurality of gate structures 221 exposed by the second opening 205, may include: using a first etching process to etch away the sacrificial gate structure 221 exposed by the bottom of the first opening 204 and the portion of the plurality of gate structures 221 exposed by the bottom of the second opening 205; and using a second etching process to etch away the portion of the plurality of fins 210 under the bottom of the first opening 204.

The first etching process may include: using a wet etching method to remove the sacrificial gate layer of the sacrificial gate structure 221 exposed by the bottom of the first opening 204 and gate layers of the portion of the plurality of gate structures 221 exposed by the bottom of the second opening 205; and removing the sacrificial gate oxidation layer of the sacrificial gate structure 221 exposed by the bottom of the first opening 204 and gate oxidation layers of the portion of the plurality of gate structures 221 exposed by the bottom of the second opening 205.

The sacrificial gate layer of the sacrificial gate structure 221 exposed by the bottom of the first opening 204 and the gate layers of the portion of the plurality of gate structures 221 exposed by the bottom of the second opening 205 may be removed by a wet etching method. The wet etching method may use an etching liquid including a TMAH solution.

The sacrificial gate oxidation layer of the sacrificial gate structure 221 exposed by the bottom of the first opening 204 and the gate oxidation layers of the portion of the plurality of gate structures 221 exposed by the bottom of the second opening 205 may be removed by a wet etching method and a dry etching method. In one embodiment, the sacrificial gate oxidation layer of the sacrificial gate structure 221 exposed by the bottom of the first opening 204 and the gate oxidation layers of the portion of the plurality of gate structures 221 exposed by the bottom of the second opening 205 may be removed by the wet etching method. The wet etching method may use an HF solution with a volume ratio between HF and H₂O of about 1:3000 to about 1:100.

The second etching process may use a dry etching method. An etching gas of the dry etching method may use a plasma gas including Cl₂ or SF₆.

A depth of the first groove 260 may be about 110 nm to about 230 nm. If the depth of the first groove 260 is smaller than 110 nm, an isolation layer formed in the first groove 260 subsequently may have a poor isolation effect. If the depth of the first groove 260 is larger than 230 nm, the fabrication process may be wasted.

The second groove 261 may expose the isolation structure 201, and may have a depth of about 60 nm to about 150 nm.

The first groove 260 and the second groove 261 may be formed in the same etching process. A fabrication process may be simplified, and the producing efficiency may be improved. Also, the first groove 260 and the second groove 261 formed in the same etching process may have high accuracy. The performance of the formed semiconductor device may be improved.

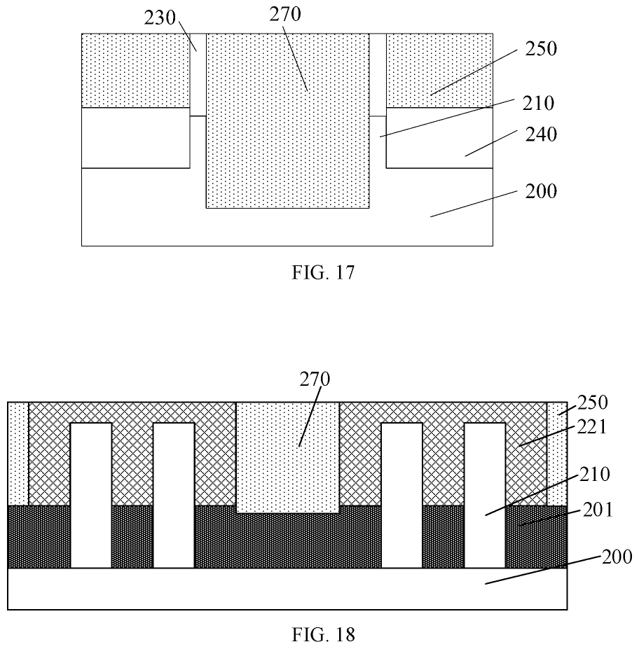

As illustrated in FIG. 17 based on FIG. 14 and FIG. 18 based on FIG. 15, isolation layers 270 may be formed in the first groove 260 and in the second groove 261 (e.g., S810 in FIG. 19).

An isolation layer 270 in the first groove 260 may isolate semiconductor devices formed in the first region I of the substrate 200 and in the third region III of the substrate 200.

An isolation layer 270 in the second groove 261 may isolate the gate structures 221 in the first region I of the substrate 200 and in the third region III of the substrate 200.

The isolation layers 270 may be formed by: forming an initial isolation layer in the first groove 260, in the second groove 261, and on the mask layer 232, to fill up the first groove 260 and the second groove 261; and planarizing the initial isolation layer and the mask layer 232 until exposing the top surface of the dielectric layer 250, to form the isolation layers 270 in the first groove 260 and in the second groove 261.

The isolation layer 270 in the first groove 260 may be used as a single-diffusion-break isolation structure, and the isolation layer 270 in the second groove 261 may separate different gate structures.

The present disclosure also provides a semiconductor device formed by fabrication methods consistent with various embodiments of the present disclosure. As illustrate in FIG. 12, the semiconductor device may include: a substrate 200 including a first region I, a second region II, and a third region III, arranged sequentially along a first direction x; a plurality of fins 210 on the first region I, the second region II, and the third region III of the substrate 200; gate structures 221 on the first region I and the third region III of the substrate 200; a dielectric layer 250 on the substrate 200; and a first groove 260 and a second groove 261 in the dielectric layer 250. The plurality of fins 210 may be discrete and parallel to the first direction x. The gate structures 221 may cross the plurality of fins 210, and may extend along a second direction y perpendicular to the first direction x. The dielectric layer 250 may cover the plurality of fins 210 and the gate structures 221, while may expose top surfaces of the gate structures 221. The first groove 260 may extend along the second direction y, and may be located on the second region II of the substrate 200. The second groove 261 may be located in the first region I and the third region III of the substrate 200.

In the present disclosure, the sacrificial gate structure and the gate structures may be formed simultaneously, and the sacrificial gate structure may occupy the position of the single-diffusion-break isolation structure. Correspondingly, the position of the single-diffusion-break isolation structure can be controlled precisely. The first groove may be formed by removing the sacrificial gate structure and fins under the bottom of the first opening. The first groove may be used for forming the single-diffusion-break isolation structure subsequently. The second groove may be formed by removing the gate structures exposed by the second opening, and may be used to formed the isolation layer separating different gate structures. The first groove and the second groove may be formed in one same etching process. The process may be simplified and the producing efficiency may be improved. Also, since the first groove and the second groove may be formed in the same etching process, the first groove and the second groove may have high accuracy. The performance of the semiconductor device may be improved.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments but may be embodied in other equivalent forms without departing from the scope of the present disclosure, which is determined by the appended claims.

What is claimed is:

1. A fabrication method for a semiconductor device, comprising:
providing a substrate, wherein the substrate includes a first region, a second region and a third region arranged sequentially along a first direction;
forming a plurality of fins on the substrate, wherein each of the plurality of fins extends parallel to the first direction from the first region to the third region through the second region;
forming a plurality of gate structures on the first region and the third region of the substrate, wherein the plurality of gate structures crosses the plurality of fins and extends along a second direction perpendicular to the first direction;
forming a sacrificial gate structure on the second region of the substrate, wherein the sacrificial gate structure crosses the plurality of fins and is parallel to the plurality of gate structures;
forming a dielectric layer over the substrate covering the plurality of fins, the plurality of gate structures, and the sacrificial gate structure, wherein the dielectric layer exposes a top surface of the sacrificial gate structure and top surfaces of the plurality of gate structures;
forming a mask layer on the dielectric layer including a first opening and a second opening, wherein the first opening is located on the second region of the substrate and exposes the sacrificial gate structure, the second opening is located on the first region and the third region of the substrate and exposes a portion of the plurality of gate structures on the first region and the third region of the substrate; and
removing the sacrificial gate structure and a portion of the plurality of fins under a bottom of the first opening, and removing the portion of the plurality of gate structures exposed by the second opening, by using the mask layer as an etch mask, to form a first groove and a second groove in the dielectric layer, wherein the first groove is located on the second region of the substrate and exposes the sacrificial gate structure, and the second groove is located on the first region and the third region of the substrate.

2. The method according to claim 1, wherein:
the mask layer is made of a material including SiNₓ, SiNB, SiCNO, SiNO, or a combination thereof.

3. The method according to claim 1, wherein:
forming the mask layer includes:
forming an initial mask material layer on the dielectric layer, wherein the initial mask material layer covers the sacrificial gate structure and the plurality of gate structures;
forming a first patterned layer on the initial mask material layer to expose a portion of the initial mask material layer on the sacrificial gate structure;
etching the initial mask material layer by using the first patterned layer as a mask, to form an initial mask layer including the first opening, wherein the first opening exposes the sacrificial gate structure and extends parallel to the second direction;
after forming the first opening, forming a second patterned layer on the initial mask layer, wherein the second mask layer exposes a portion of the initial mask layer on the portion of the plurality of gate structures on the first region and the third region of the substrate; and
etching the initial mask layer by using the second patterned layer as a mask, to form the mask layer and the second opening in the mask layer, wherein the second opening exposes the dielectric layer on the first region, the second region, and the third region of the substrate, and also expose the portion of the plurality of gate structures on the first region and the third region of the substrate.

4. The method according to claim 1, further including:
forming an isolation layer in the first groove and an isolation layer in the second groove.

5. The method according to claim 4, wherein forming the isolation layer in the first groove and the isolation layer in the second groove includes:
forming an initial isolation layer in the first groove, in the second groove and on the mask layer, wherein the initial isolation layer fills up the first groove and the second groove; and
planarizing the initial isolation layer until exposing a top surface of the dielectric layer, to form the isolation layer in the first groove and the isolation layer in the second groove.

6. The method according to claim 1, wherein:
etching away the sacrificial gate structure and the portion of the plurality of fins under a bottom of the first opening, and etching away the portion of the plurality of gate structures exposed by the second opening, use a dry etching process, a wet etching process, or a combination thereof.

7. The method according to claim 1, wherein:
each gate structure of the plurality of gate structures includes a gate oxidation layer and a gate layer on the gate oxidation layer;
the gate oxidation layer is made of a material including SiO₂; and
the gate layer is made of a material including polycrystalline silicon.

8. The method according to claim 1, wherein:
each gate structure of the plurality of gate structures includes a gate dielectric layer and a gate layer on the gate dielectric layer;
the gate dielectric layer is made of a high-K dielectric material; and
the gate layer is made of a metal including Cu, W, Ni, Cr, Ti, Ta, Al, or a combination thereof.

9. The method according to claim 1, after forming the sacrificial gate structure and the plurality of gate structures, and before forming the dielectric layer, further including:
forming source/drain doped layers in the plurality of fins at sides of each gate structure of the plurality of gate structures and at sides of the sacrificial gate structure.

10. The method according to claim 9, after forming the sacrificial gate structure and the plurality of gate structures, and before forming the source/drain doped layers, further including:
forming spacers on the sides of each gate structure of the plurality of gate structures and on the sides of the sacrificial gate structure.

11. The method according to claim 1, wherein:
the first groove has a depth of about 110 nm to about 230 nm.

12. The method according to claim 1, before forming the plurality of gate structures, further including:
forming an isolation structure on the substrate, wherein:
the isolation structure covers a portion of sidewalls of the plurality of fins;
the plurality of gate structures is located on a surface of the isolation structure; and
the second groove exposes the isolation structure.

13. The method according to claim 1, wherein:
the sacrificial gate structure includes a sacrificial gate oxidation layer and a sacrificial gate layer on the sacrificial gate oxidation layer;
the sacrificial gate oxidation layer is made of a material including SiO₂; and
the sacrificial gate layer is made of a material including polycrystalline silicon.

14. The method according to claim 1, wherein the sacrificial gate structure is formed when forming the plurality of gate structures.

15. A semiconductor device, comprising:
a substrate, wherein the substrate includes a first region, a second region and a third region arranged sequentially along a first direction;
a plurality of fins on the substrate, wherein each of the plurality of fins is discrete from each other and extends parallel to the first direction;
a plurality of gate structures on the first region and the third region of the substrate, wherein the plurality of gate structures crosses the plurality of fins and extends along a second direction perpendicular to the first direction;
a dielectric layer on the substrate covering the plurality of fins, the plurality of gate structures, and the sacrificial gate structure, wherein the dielectric layer exposes a top surface of the sacrificial gate structure and top surfaces of the plurality of gate structures; and
a first groove and a second groove in the dielectric layer, wherein the first groove is located on the second region of the substrate, and the second groove is located on the first region and the third region of the substrate.

16. The device according to claim 15, wherein:
each gate structure of the plurality of gate structures includes a gate oxidation layer and a gate layer on the gate oxidation layer;
the gate oxidation layer is made of a material including SiO₂; and
the gate layer is made of a material including polycrystalline silicon.

17. The device according to claim 15, wherein:
each gate structure of the plurality of gate structures includes a gate dielectric layer and a gate layer on the gate dielectric layer;
the gate dielectric layer is made of a high-K dielectric material; and
the gate layer is made of a metal including Cu, W, Ni, Cr, Ti, Ta, Al, or a combination thereof.

18. The device according to claim 15, wherein:
the first groove has a depth of about 110 nm to about 230 nm.

19. The device according to claim 15, wherein:
the second groove has a depth of about 60 nm to about 150 nm.

20. The device according to claim 15, further including isolation layers in the first groove and in the second groove.
